(19) United States
(12) Patent Application Publication
(10) Pub. No.: US 2026/0271386 A1
(43) Pub. Date: Sep. 10, 2026

(54) SEMICONDUCTOR PROCESS FOR SIMULTANEOUSLY FORMING A SEMICONDUCTOR STRUCTURE WITH FEATURES OF D-MODE AND E-MODE GAN DEVICES

(71) Applicant: United Microelectronics Corp., Hsin-Chu City (TW)

(72) Inventors: Chih-Tung Yeh, Taoyuan City (TW); Ruey-Chyr Lee, Taichung City (TW); Wen-Jung Liao, Hsinchu City (TW)

(73) Assignee: United Microelectronics Corp., Hsin-Chu City (TW)

(21) Appl. No.: 19/663,217

(22) Filed: Apr. 29, 2026

Related U.S. Application Data
(62) Division of application No. 17/886,491, filed on Aug. 12, 2022.

(30) Foreign Application Priority Data
Jul. 7, 2022 (TW) 111125477

(51) Int. Cl. H10D 84/84; H10D 30/01; H10D 30/47; H10D 62/17; H10D 62/824; H10D 62/85; H10D 62/852; H10D 84/01; H10D 84/05; H10P 50/24; H10P 50/28; H10P 50/64; H10W 74/10

(52) U.S. Cl. CPC H10D 84/84; H10D 30/015; H10D 30/475; H10D 62/343; H10D 62/824; H10D 62/8503; H10D 62/852; H10D 84/0123; H10D 84/05; H10P 50/283; H10W 74/137; H10W 74/147; H10P 50/242; H10P 50/642

(57) ABSTRACT

A semiconductor process of simultaneously forming features of D-mode and E-mode GaN devices, including forming a p-GaN layer on an AlGaN layer in a first region of a substrate, sequentially forming a Al-based passivation layer and a Si-based passivation layer on the AlGaN layer and p-GaN layer, and performing a photolithography process to form gate contact openings simultaneously in the first region and a second region of the substrate, wherein the gate contact opening on first region extends through the Si-based passivation layer and Al-based passivation layer to the p-GaN layer, and the gate contact opening in second region extends through the Si-based passivation layer and Al-based passivation layer to the AlGaN layer, and the photolithography process includes an etching process and a first wet etching process, and the etching process removes the Si-based passivation layer and the first wet etching process removes the Al-based passivation layer.

### CROSS REFERENCE TO RELATED APPLICATIONS

This application is a division of U.S. application Ser. No. 17/886, 491, filed on Aug. 12, 2022. The content of the application is incorporated herein by reference.

### BACKGROUND OF THE INVENTION

### 1. Field of the Invention

The present invention relates generally to a semiconductor structure, and more specifically, to a semiconductor structure with features of D-mode and E-mode GaN devices and semiconductor process Thereof.

### 2. Description of the Prior Art

Most of semiconductor devices currently available in the world are silicon-based semiconductor using silicon as their substrate and channel. However, in the application of high-voltage, high-power devices, silicon-based devices may suffer high power consumption since their on-state resistance RDS(on) is too large. Furthermore, in high-frequency operation, silicon-based device has relatively lower switch frequency, thus its performance is no match for those using wide band gap compound semiconductor material like gallium nitride (GaN) or silicon carbide (SiC). In comparison to conventional silicon-based material, Wide band gap compound semiconductor material like GaN is provided with larger band gap, lower on-state resistance, thus it is more durable and applicable in high temperature, high voltage, high frequency and high current applications, and also with better energy conversion efficiency. Thus, GaN device is provided all kinds of excellent properties required in the semiconductor device like good heat dissipation, small size, lower power consumption and high power, which is suitable for the application of power semiconductor. With the urgent demand in high-end industry like 5G communication and electric car, GaN material has emerged to be a promising candidate of the third generation semiconductor materials in the future.

There are primarily two modes of GaN device, i.e. depletion mode (D-mode) and enhancement mode (E-mode). With respect to D-mode GaN device, since a conductive channel of high concentration two-dimensional electron gas (2DEG) will be formed at the heterojunction between AlGaN/GaN layers due to spontaneous polarization and piezoelectric polarization effect, the D-mode GaN device is normally-on without applying gate voltage, while E-mode device realizes its normally-off characteristic through setting an additional p-type GaN (p-GaN) layer on the aforementioned AlGaN layer to deplete the 2DEG channel below. The aforementioned two modes of GaN devices have their advantages, disadvantages and their suitable applications.

The application of current GaN device has advanced from simple discrete components to monolithic half bridge circuits and power fin effect transistors (FETs) with integrated drivers, and further to the field of system-on-chip (SoC), in hope of integrating functions of the power FETs, drivers, level translator circuits and logic modules into one single chip and reducing entire production volume and manufacturing cost. However, since E-mode GaN device is inherently provided with an additional p-GaN layer than the D-mode GaN device, it is difficult to integrate them in the same semiconductor process, especially for the cause of etching steps in photolithography process. The layer structures of GaN devices of different modes will have quite different etching selectivity in the same etching process, so that the layer structures of GaN devices will be damaged due to over-etching effect during the etching process, thereby impacting their electrical performance.

### SUMMARY OF THE INVENTION

In the light of the aforementioned shortcomings of conventional skills, the present invention hereby provides a novel semiconductor process, with features of setting specific device passivation layers and adopting specific etching steps to prevent layer structures in two different kinds of GaN devices from damage in the same etching process. In this way, the manufactured D-mode and E-mode GaN devices are both provided with better electrical performance.

One aspect of the present invention is to provide a semiconductor device with features of depletion mode (D-mode) and enhancement mode (E-mode) GaN devices, including structures of a substrate with a first region and a second region defined thereon, a GaN channel layer on the substrate, a AlGaN layer on the GaN channel layer, a p-GaN layer on the AlGaN layer in the first region, a Al-based passivation layer on the AlGaN layer and the p-GaN layer, and gate contact openings, wherein one of the gate contact openings on the first region extends through the Al-based passivation layer to a top surface of the p-GaN layer, and one of the gate contact openings on the second region extends through the Al-based passivation layer to a surface of the AlGaN layer, and the top surface of p-GaN layer and the surface of AlGaN layer are both flat surfaces without recess feature.

Another aspect of the present invention is to provide a semiconductor process of simultaneously forming features of depletion mode (D-mode) and enhancement mode (E-mode) GaN devices, including steps of providing a substrate with a first region and a second region defined thereon and with a GaN channel layer and a AlGaN layer sequentially formed thereon, forming a p-GaN layer on the AlGaN layer in the first region, sequentially forming a Al-based passivation layer and a Si-based passivation layer on the AlGaN layer and the p-GaN layer, and performing a photolithography process to form gate contact openings simultaneously in the first region and the second region, wherein one of the gate contact openings on the first region extends through the Si-based passivation layer and the Al-based passivation layer to a top surface of the p-GaN layer, and one of the gate contact openings in the second region extends through the Si-based passivation layer and the Al-based passivation layer to a surface of the AlGaN layer, and the photolithography process includes an etching process and a first wet etching process, and the etching process removes the Si-based passivation layer and the first wet etching process removes the Al-based passivation layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 to FIG. 6 are schematic cross-sections illustrating a process flow of manufacturing the semiconductor structure with features of depletion mode (D-mode) and enhancement mode (E-mode) GaN devices in accordance with the preferred embodiment of the present invention.

Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

In addition, spatially relative terms, such as “beneath,” “below,” “lower,” “above,” “upper,” and the like, may be used herein for ease of description to describe one element or feature's relationship to another element(s) or feature(s) as illustrated in the figures.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or heterogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

A semiconductor process of simultaneously manufacturing features of depletion mode (D-mode) and enhancement mode (E-mode) GaN devices will now be described in following embodiments. GaN device is a kind of field effect transistor (FET) incorporating a junction between two materials with different band gaps (i.e., a heterojunction) as a channel instead of using a doped region as a channel as is generally the case for metal oxide semiconductor field effect transistors (MOSFETS).

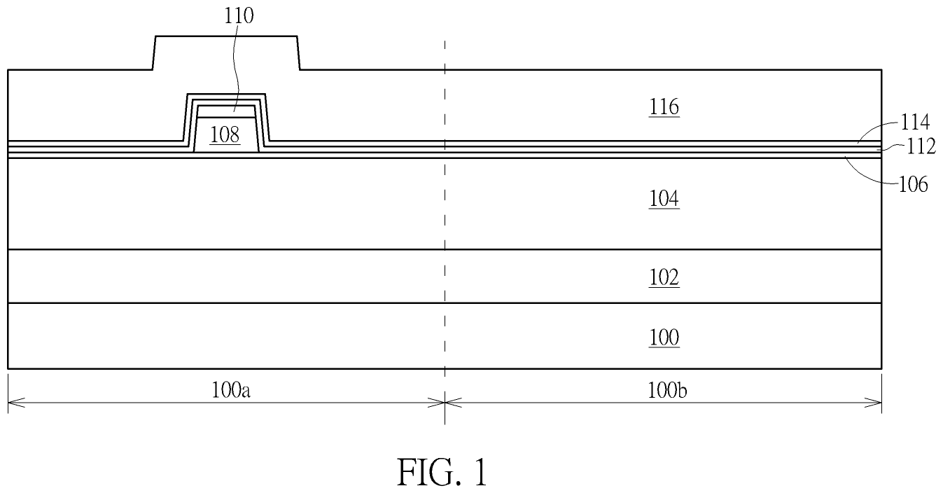

Please refer first to FIG. 1. The GaN device of present invention is constructed on a substrate 100. The substrate 100 may be a silicon layer having <111> lattice plane to serve as a base for setting components of the device. The Si <111> layer may provide an optimal lattice matching with overlying layers, such as an overlying gallium nitride (GaN) buffer layer or superlattice layer, in order to prevent problems like dislocations or defects resulted from mismatching lattice constants and thermal expansion coefficients between two materials during later heteroepitaxy process. In some embodiments, the substrate 100 may be made of compound semiconductor like silicon carbide (Sic), gallium arsenic (GaAs), indium arsenide (InAs) or indium phosphide (InP). In some embodiments, the substrate 100 may be made of semiconductor alloy like silicon germanium (SiGe), silicon germanium carbide (SiGeC), gallium arsenic phosphide (GaAsP) or gallium indium phosphide (GaInP). In the preferred embodiment of present invention, a first region 100a and a second region 100b are defined on the substrate 100, wherein D-mode GaN devices and E-mode GaN devices will be formed respectively on them in later process.

Refer still to FIG. 1. In the structure of GaN device of the present invention, a buffer layer 102 is formed on the substrate 100. The buffer layer 102 is formed and defined as a high-resistance layer to increase the breakdown voltage of GaN device and reduce vertical current leakage thereof. The resistance of buffer layer 102 is higher than the resistivity of channel layer be to formed in later process. In some embodiments, the buffer layer 102 includes one or more group [symbol] -V compound semiconductor layers. Examples of these group [symbol] -V compound semiconductors include but not limited to gallium nitride (GaN), aluminum gallium nitride (AlGaN), Indium gallium nitride (InGaN) and Indium aluminum gallium nitride (InAlGaN). In some embodiments, the buffer layer 102 may also be doped with dopants to attain a predetermined high resistivity. In some embodiments, these dopants are p-type dopant. In some embodiments, the buffer layer 102 includes GaN doped with p-type dopant (p-GaN). Examples of the p-type dopant include but not limited to carbon (C), iron (Fe), magnesium (Mg) or zinc (Zn). In other embodiments, structures like additional nucleation layer and superlattice layer stack may be further formed between the buffer layer 102 and substrate 100 to further prevent dislocation or defect issue. In addition, the buffer layer 102 may also be shaped into mesa structure to further improve the isolation effect between devices.

Refer still to FIG. 1. In the structure of GaN device of the present invention, a GaN channel layer 104 is formed over the buffer layer 102. In the embodiment of present invention, the GaN channel layer 104 has a resistivity lower than the one of buffer layer 102 in order to improve current performance of the GaN device. In some embodiments, the channel layer 104 includes one or more Group [symbol] -V compound layers. Examples of theses Group [symbol] -V compound materials include but not limited to AlGaN, InGaN and InAlGaN. In some embodiments, the GaN channel layer 104 may include alternatingly arranged p-doped and n-doped Group [symbol] -V compound layers.

Furthermore, an AlGaN layer 106 is further formed over the GaN channel layer 104 to function as a barrier layer. A heterojunction is formed between the GaN channel layer 104 and the AlGaN layer 106, with a band gap discontinuity exists therebetween, so that electrons produced by piezoelectricity in the AlGaN layer 106 would fall into the GaN channel layer 104, thereby creating a thin layer of highly mobile conducting electrons, i.e. two dimensional electron gas (2DEG), adjacent the interface between the two layer structures. Please note that the aforementioned embodiment is a case of n-type GaN device, wherein the electrons in the 2DEG are charge carriers in the GaN channel layer 104, and the high electron mobility transistor (HEMT) may be constituted after forming components like gate and source/drain on the barrier layer in later processes. In other embodiment, for example in p-type GaN device, the charge carriers formed between the AlGaN layer 106 and the GaN channel layer 104 would be two dimensional hole gas (2DHG), and the high hole mobility transistor (HHMT) may be constituted after forming components like gate and source/drain on the barrier layer in later processes.

Refer still to FIG. 1. In the embodiment of present invention, a p-type GaN (p-GaN) layer 108 is further formed on the AlGaN layer 106 in the first region 100a, in order to deplete the charge carriers generated in the GaN channel layer 104 below, so as to form the E-mode device with normally-off state. In some embodiments, p-GaN layer 108 has a constant doping concentration. Examples of the p-type dopant in the p-GaN layer 108 includes but not limited to carbon (C), iron (Fe), magnesium (Mg) and zinc (Zn). Other additional p-GaN layers with different doping concentration may also be formed over the p-GaN layer 108 to increase gate operation voltage of the device. Please note that in the preferred embodiment of present invention, a titanium nitride (TiN-based) hard mask layer 110 is further formed over the p-GaN layer 108 to serve as a hard mask for the process of patterning the p-GaN layer 108 and as a barrier between the p-GaN layer 108 and metal gates to be formed in later process. The TiN-based hard mask layer may also provide good Schottky contact. Gate patterns of the GaN device are generally defined by the p-GaN layer 108 and the TiN-based hard mask layer 110. The aforementioned buffer layer 102, GaN channel layer 104, AlGaN layer 106 and p-GaN layer 108 may all be in-situ formed in the same process chamber without changing chamber, thereby saving cost and reducing pollution in the whole process.

Refer still to FIG. 1. In the embodiment of present invention, a conformal Al-based passivation layer 112, a first Si-based passivation layer 114 and a second Si-based passivation layer 116 are further formed sequentially on the AlGaN layer 106, p-GaN layer 108 and TiN-based hard mask layer 110, which may provide isolation effect for the components like gate and source/drain of the GaN device and prevent current leakage. The aforementioned passivation layers may also function as dielectric layers for field plate structures in the GaN device. In the embodiment, the material of Al-based passivation layer 112 may be aluminum oxide (Al₂O₃) or aluminum nitride (ALN), the material of first Si-based passivation layer 114 may be silicon nitride (Si₃N₄), and the material of second Si-based passivation layer 116 may be silicon oxide (SiO₂). Please note that Si-based passivation layer 114, 116 may not be set in other embodiment of the present invention. Alternatively, only single Si-based passivation layer will be formed in the device. In addition, the TiN-based hard mask layer 110 may also be omitted in other embodiment, so that the passivation layer will be formed directly on the top surface of the p-GaN layer 108. The aforementioned Al-based passivation layer 112 may be formed through atomic layer deposition (ALD), and the first Si-based passivation layer 114 and the second Si-based passivation layer 116 may be formed through plasma-enhanced chemical vapor deposition (PECVD).

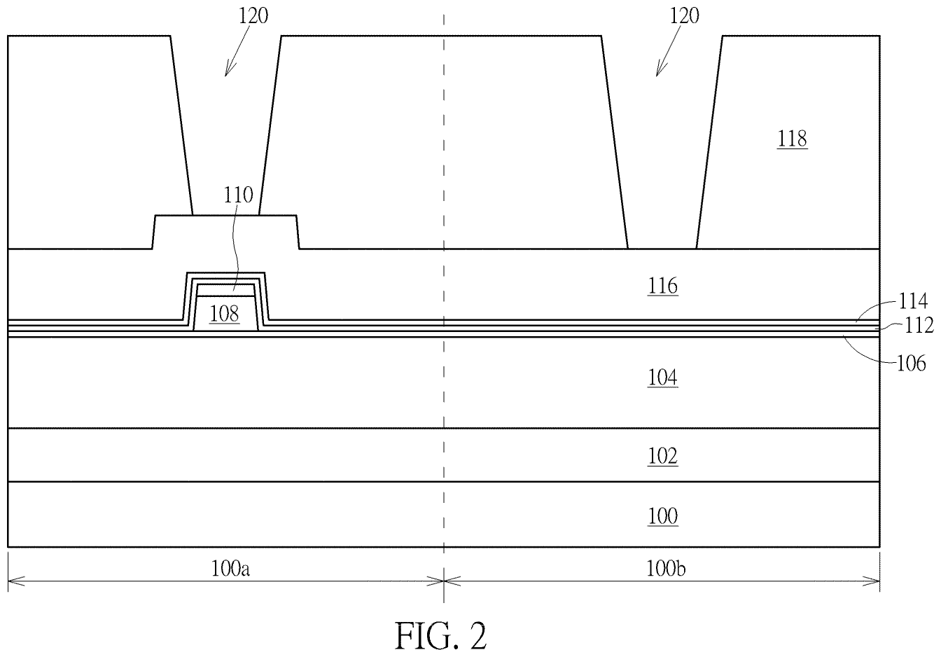

Please refer next to FIG. 2. A photoresist 118 is formed over the second Si-based passivation layer, and gate contact opening patterns 120 are formed in the photoresist 118 through a photolithography process. Theses gate contact opening patterns 120 define the gate patterns of GaN devices to be formed on the first region 100a and the second region 100b in later process, wherein the gate contact opening pattern 120 on the first region 100a overlaps and aligns with the p-GaN layer 108 below.

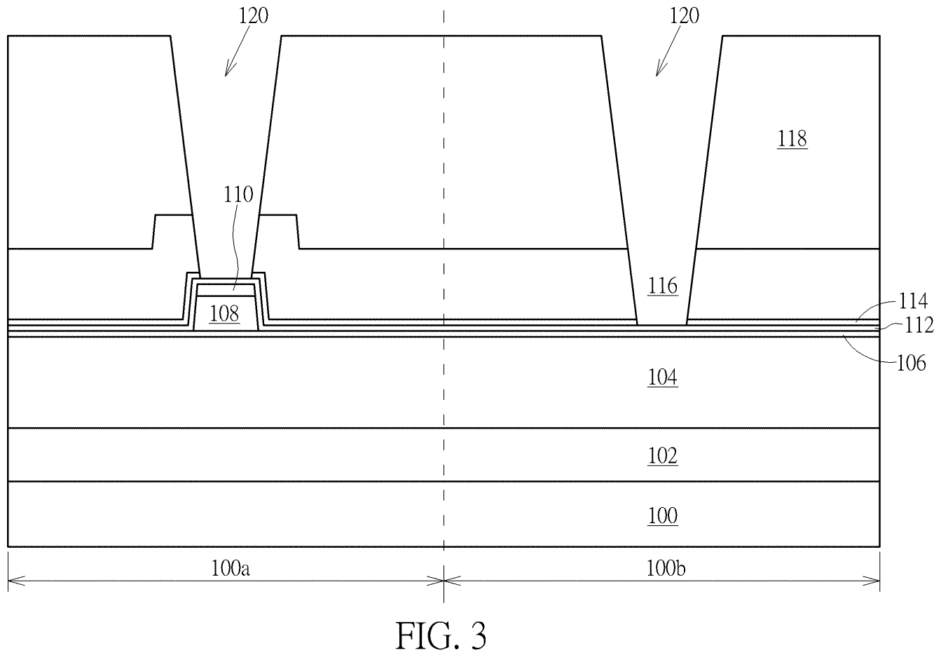

Please refer next to FIG. 3. Perform an etching process using the photoresist 118 as an etching mask to remove the exposed first Si-base passivation layer 114 and second Si-base passivation layer 116, so as to form gate contact opening 120 in the Al-based passivation layer 112 and the second Si-base passivation layer 116. The underlying Al-based passivation layer 112 functions as an etch stop layer in this etching process. In the preferred embodiment of present invention, this etching process may include a dry etching process and a wet etching process, wherein the dry etching process uses etch gases like trifluoromethane (CHF₃), sulfur(VI) fluoride (SF₆) and helium (He) to remove Si-based passivation layers 114, 116, while the wet etching process uses hydrofluoric acid (HF) and phosphoric acid (H₃PO₄) to respectively remove the second Si-based passivation layer 116 made of silicon oxide and first Si-based passivation layer 114 made of silicon nitride and expose the underlying Al-based passivation layer 112.

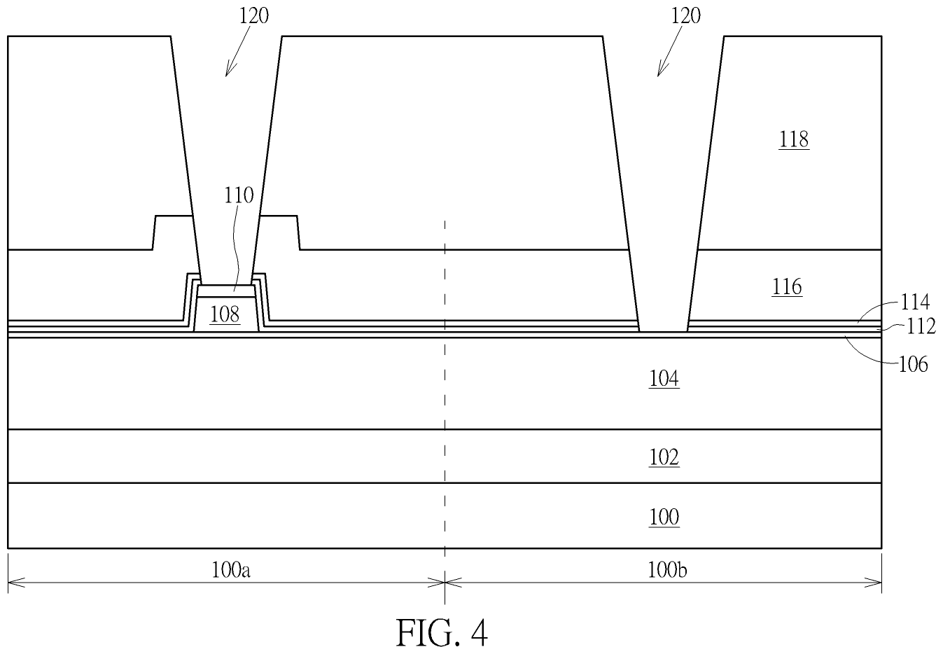

Please refer next to FIG. 4. Perform another wet etching process to remove the Al-based passivation layer 112 exposed from the gate contact opening patterns 120, so as to expose the TiN-based hard mask layer 110 and the AlGaN layer 106 respectively on the first region 100a and the second region 100b. In the preferred embodiment of present invention, the etchant used in this wet etching process may include 80% phosphoric acid (H₃PO₄), 5% nitric acid (HNO₃) and 10% water, which has good etch rate to Al-based passivation layer like aluminum oxide (Al₂O₃) and aluminum nitride (ALN) but inert to the material like titanium nitride (TiN) or AlGaN epitaxy, so that the wet etching process may stop on the TiN-based hard mask layer 110 and the AlGaN layer 106 respectively on the first region 100a and the second region 100b without damaging the layer structures below. Please note that in the embodiment without TiN-based hard mask layer 110, neither the p-GaN layer 108 below will be damaged by the aforementioned etchant.

In conventional skill, the aforementioned steps of forming gate contact openings 120 in FIG. 2 to FIG. 5 are usually performed individually in the first region 100a and the second region 100b . That means two photoresists and two photolithography processes are necessary to form the gate contact openings 120 on the two regions in conventional approach. They can't be integrated in single photolithography process. This conventional approach is not only complicated, but also difficult to control process cycle and queue time. Integrating the patterning processes on the two regions into single photolithography process may significant reduce process cost and production cycle. Furthermore, conventional dry etching process is apt to damage the stop layers on the two regions if using only single photolithography process to form the gate contact openings 120 on the two regions. Take the layer structures of present invention as an example, the stop layers on the two regions are TiN-based hard mask layer 110 and AlGaN layer 106 respectively, which have quite large etching selectivity in the dry etching process, thus it is difficult to prevent both of the two layers from damage and over-etching usually happens in the process. The advantage of present invention is that wet etching process and specific etchants are adopted to remove the Al-based passivation layer 112, thus the underlying stop layers made of different materials will not be damaged.

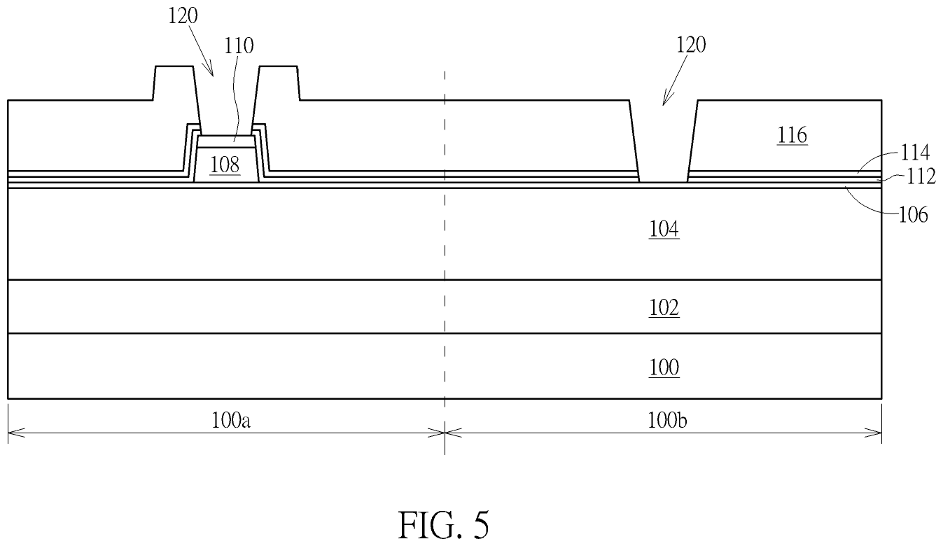

Please refer next to FIG. 5. After the exposed Al-based passivation layer 112 is removed, the photoresist is then removed to expose the underlying second Si-based layer 116. This step may include wet bench process using photoresist stripper, such as strongly alkaline or weakly alkaline solvent, to completely remove the remaining photoresist. The step of removing the photoresist would not damage the exposed TiN-based hard mask layer 110 and Al-based passivation layer 112.

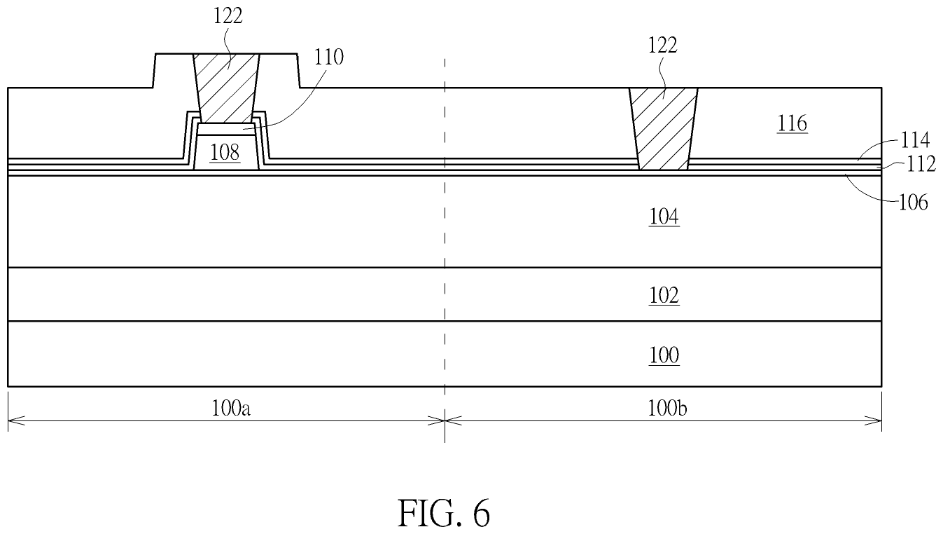

Lastly, please refer to FIG. 6. After the photoresist 118 is removed, metal or metal compound is filled into the gate contact openings 120 to form the gates 122 of GaN devices. The material of gate 122 may be titanium (Ti) or titanium nitride (TiN). In the embodiment of present invention, the gate 122 on the first region 100a is connected with the TiN-based hard mask layer 110 below (or is connected with the p-GaN layer 108 below if TiN-based hard mask layer 110 is omitted) and is further connected to the underlying AlGaN layer 106 through the p-GaN layer 108, so as to function as a gate for E-mode GaN device.

The sources/drains of GaN devices may be formed subsequently after the gates 122 of GaN devices are manufactured, so that the gate, source/drain and the channel layer constitutes collectively a GaN device. Please note that in other embodiment, source/drain may be formed before the gate 122, for example formed after the p-GaN layer 108 and before the gate 122, or may be formed simultaneously with the gate 122. Since the source/drain of GaN device is not an essential feature of present invention, these parts will not be shown in the figures and relevant details will also not be provided in the specification for the sake of concision.

According to the semiconductor process provided above, the present invention hereby provides a semiconductor device with features of D-mode and E-mode GaN devices. As shown in FIG. 6, the structure includes a substrate 100 with a first region 100a and a second region 100b defined thereon, a GaN channel layer 104 on the substrate 100, a AlGaN layer 106 on the GaN channel layer 104, a p-GaN layer 108 on the AlGaN layer 106 in the first region 100a, a Al-based passivation layer 112 on the AlGaN layer 106 and the p-GaN layer 108 and gates, wherein the gate 122 on the first region 100a is connected with a top surface of the p-GaN layer 108 below, and the gate 122 on the second region directly contact the underlying AlGaN layer, and the top surfaces of p-GaN layer 108 and AlGaN layer 106 are both flat surfaces without recess feature since over-etching doesn't happen in the aforementioned gate opening process.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A semiconductor process of simultaneously forming features of depletion mode (D-mode) and enhancement mode (E-mode) GaN devices, comprising:
providing a substrate with a first region and a second region defined thereon and with a GaN channel layer and an AlGaN layer sequentially formed thereon;
forming a p-GaN layer on said AlGaN layer in said first region;
sequentially forming an Al-based passivation layer and a Si-based passivation layer on said AlGaN layer and said p-GaN layer; and
performing a photolithography process to form gate contact openings simultaneously in said first region and said second region, wherein one of said gate contact openings on said first region extends through said Si-based passivation layer and said Al-based passivation layer to a top surface of said p-GaN layer, and one of said gate contact openings in said second region extends through said Si-based passivation layer and said Al-based passivation layer to a surface of said AlGaN layer, and said photolithography process comprises an etching process and a first wet etching process, and said etching process removes said Si-based passivation layer and said first wet etching process removes said Al-based passivation layer.

2. The semiconductor process of simultaneously forming features of depletion mode (D-mode) and enhancement mode (E-mode) GaN devices of claim 1, wherein said photolithography process further comprises forming a photoresist on said Si-based passivation layer and forming gate contact opening patterns in said photoresist.

3. The semiconductor process of simultaneously forming features of depletion mode (D-mode) and enhancement mode (E-mode) GaN devices of claim 1, wherein said etching process comprise a dry etching process and a second wet etching process, and said dry etching process uses trifluoromethane (CHF₃), sulfur(VI) fluoride (SF₆) and helium (He).

4. The semiconductor process of simultaneously forming features of depletion mode (D-mode) and enhancement mode (E-mode) GaN devices of claim 3, wherein said Si-based passivation layer comprises silicon oxide layer, silicon nitride layer or both of them, and an etchant used in said second wet etching process is hydrofluoric acid (HF) and phosphoric acid (H₃PO₄) or both of them.

5. The semiconductor process of simultaneously forming features of depletion mode (D-mode) and enhancement mode (E-mode) GaN devices of claim 1, an etchant used in said first wet etching process comprises phosphoric acid (H₃PO₄), nitric acid (HNO₃) and water.

6. The semiconductor process of simultaneously forming features of depletion mode (D-mode) and enhancement mode (E-mode) GaN devices of claim 5, where a material of said Al-based passivation layer is aluminum oxide (Al₂O₃) or aluminum nitride (ALN).

7. The semiconductor process of simultaneously forming features of depletion mode (D-mode) and enhancement mode (E-mode) GaN devices of claim 2, further comprising forming metal gates or metal compound gates on said top surface of said p-GaN layer and on said surface of said AlGaN Layer exposed from said gate contact openings.

8. The semiconductor process of simultaneously forming features of depletion mode (D-mode) and enhancement mode (E-mode) GaN devices of claim 1, further comprising forming a titanium nitride hard mask layer on said p-GaN layer, and one of said gate contact openings on said first region extends through said Al-based passivation layer to a top surface of said titanium nitride hard mask layer.
